(19) United States
(12) Patent Application Publication
(10) Pub. No.: US 2010/0175554 A1
(43) Pub. Date: Jul. 15, 2010

(54) COOLING SYSTEM WITH DEBRIS FILTERING

(75) Inventors: Keith Huddleston, Austin, TX (US); Jack M. Burns, Leander, TX (US); Jonathan Jordan, Round Rock, TX (US)

Correspondence Address: HAYNES AND BOONE, LLP;IP Section, 2323 Victory Avenue, Suite 700, Dallas, TX, 75219, US

(73) Assignee: DELL PRODUCTS L.P., Round Rock, TX (US)

(21) Appl. No.: 12/354,041

(22) Filed: Jan. 15, 2009

(51) Int. Cl. B01D 46/00; H05K 7/20

(52) U.S. Cl. 95/273; 361/679.48; 361/679.47; 55/471

(57) ABSTRACT

A cooling system includes a fan chassis housing a fan. A fluid outlet is defined by the fan chassis and located adjacent the fan such that a fluid flow path is defined from the fan, through the fluid outlet, and out of the fan chassis. A filter coupling wall is located in the fan chassis and adjacent to the fluid flow path. A debris filter is located along the filter coupling wall and adjacent to at least a portion of the fluid flow path.

### BACKGROUND

The present disclosure relates generally to information handling systems, and more particularly to a cooling system with debris filtering for use in an information handling system.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

As the power of IHSs continues to increase, the heat output of components in the IHS increases as well. The cooling of these components can raise a number of issues.

For example, in portable IHSs such as, for example, notebook IHSs, the heat output of components may heat the outer surfaces of the IHS to a temperature that may be uncomfortable to a user. Typically, in order to dissipate this heat, a combination of heat sinks and fans are used. A heat sink may be coupled to the heat producing component in the IHS, and a fan may be used to direct air from an air intake that is defined by the IHS chassis and through the heat sink. By directing air through the heat sink, the heat produced by the heat producing component is dissipated such that the temperature of the outer surfaces on the IHS does not become uncomfortable for the user. However, air from the air intake typically includes debris. Over time, as the fan directs the air towards the heat sink, the debris may accumulate at the heat sink air intake. As more and more debris accumulates, the airflow from the fan through the heat sink may become blocked by the accumulated debris, which, in turn, reduces the dissipation of heat in the system and can allow the temperature of the outer surfaces on the IHS to reach an uncomfortable level.

Some solutions to this problem include providing a debris filter between the fan and the heat sink air intake. All of the air that is directed from the fan will then pass through the debris filter before entering the heat sink air intake. As debris accumulates on the debris filter, it may be cleaned or replaced. However, even when clean, such a debris filter provides an obstacle that reduces the airflow produced by the fan and provided through the heat sink, thus reducing the heat dissipated by the system. Such solutions require the fans to operate at higher fan speeds relative to systems without debris filters, which increases system noise, reduces fan life, and lowers the cooling efficiency of the system.

Accordingly, it would be desirable to provide an improved cooling system with debris filtering absent the disadvantages discussed above.

### SUMMARY

According to one embodiment, a cooling system includes a fan chassis housing a fan, a fluid outlet defined by the fan chassis and located adjacent the fan such that a fluid flow path is defined from the fan, through the fluid outlet, and out of the fan chassis, a filter coupling wall located in the fan chassis and adjacent to the fluid flow path, and a debris filter located along the filter coupling wall and adjacent to at least a portion of the fluid flow path.

### BRIEF DESCRIPTION OF THE DRAWINGS

FIG. 1 is a schematic view illustrating an embodiment of an IHS.

FIG. 2 is a top view illustrating an embodiment of an IHS chassis.

FIG. 3a is a perspective view illustrating an embodiment of a fan chassis used in the IHS chassis of FIG. 2.

FIG. 3b is a top view illustrating an embodiment of the fan chassis of FIG. 3a.

FIG. 3c is a cut-away view illustrating an embodiment of the fan chassis of FIGS. 3a and 3b.

FIG. 4 is a perspective view illustrating an embodiment of a debris filter used with the fan chassis of FIGS. 3a, 3b and 3c.

FIG. 5 is a perspective view illustrating an embodiment of a debris filter used with the fan chassis of FIGS. 3a, 3b and 3c.

FIG. 6a is a flow chart illustrating an embodiment of a method for filtering debris from a cooling system.

FIG. 6b is a cut-away view illustrating an embodiment of the fan chassis of FIGS. 3a, 3b and 3c during operation and including the debris filter of either FIG. 4 or FIG. 5.

FIG. 6c is a top view illustrating an embodiment of the fan chassis of FIGS. 3a, 3b and 3c including the debris filter of either FIG. 4 or FIG. 5 and coupled to the IHS chassis of FIG. 2.

FIG. 7a is a top view illustrating an embodiment of a fan chassis used with the IHS chassis of FIG. 2.

FIG. 7b is a perspective view illustrating an embodiment of a filter coupling wall located in the fan chassis of FIG. 7a.

FIG. 8a is a cut-away view illustrating an embodiment of the fan chassis of FIG. 7a during operation and including the debris filter of either FIG. 4 or FIG. 5 coupled to the filter coupling wall of FIG. 7b.

FIG. 8b is a perspective view illustrating an embodiment of the debris filter of FIG. 4 coupled to the filter coupling wall of FIG. 7b.

FIG. 8c is a perspective view illustrating an embodiment of the debris filter of FIG. 5 coupled to the filter coupling wall of FIG. 7b.

FIG. 8d is a top view illustrating an embodiment of the fan chassis of FIG. 7a including the debris filter of either FIG. 4 or FIG. 5 and coupled to the IHS chassis of FIG. 2.

FIG. 9a is a top view illustrating an embodiment of a fan chassis used with the IHS chassis of FIG. 2.

FIG. 9b is a perspective view illustrating an embodiment of a filter coupling wall door that is located on the fan chassis of FIG. 9a.

FIG. 10a is a top view illustrating an embodiment of the fan chassis of FIG. 7a with the filter coupling wall door of FIG. 9b in an open position and including the debris filter of either FIG. 4 or FIG. 5.

FIG. 10b is a perspective view illustrating an embodiment of the debris filter of FIG. 4 coupled to the filter coupling wall door of FIG. 9b.

FIG. 10c is a perspective view illustrating an embodiment of the debris filter of FIG. 5 coupled to the filter coupling wall door of FIG. 9b.

FIG. 10d is a top view illustrating an embodiment of the fan chassis of FIG. 9a including the debris filter of either FIG. 4 or FIG. 5 and coupled to the IHS chassis of FIG. 2.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

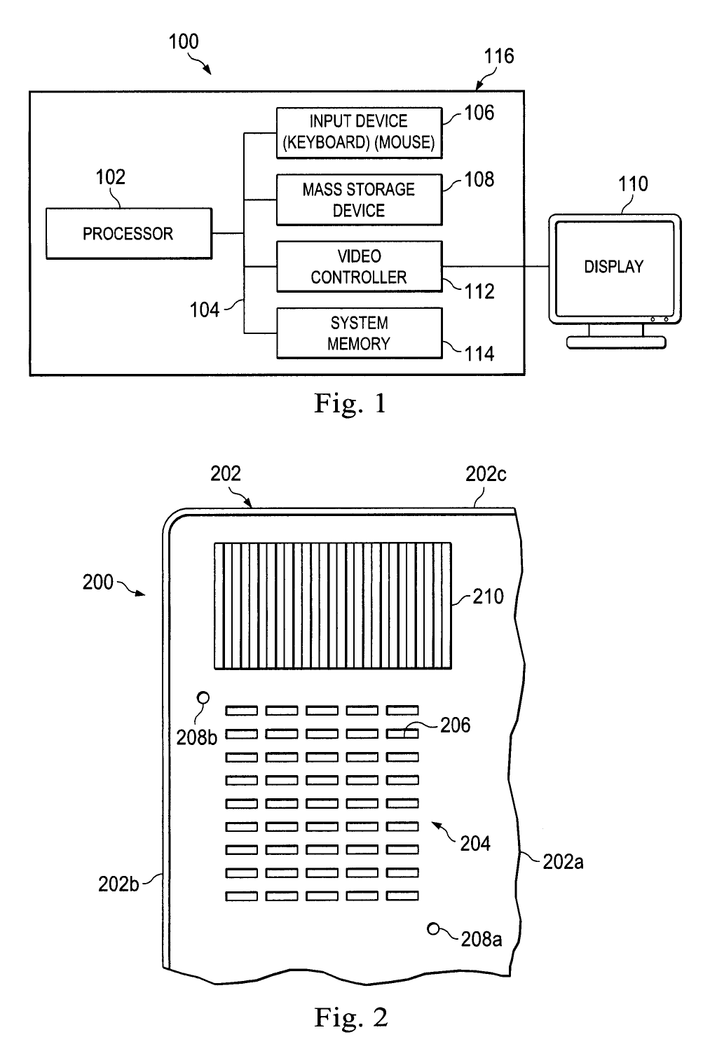

In one embodiment, IHS 100, FIG. 1, includes a processor 102, which is connected to a bus 104. Bus 104 serves as a connection between processor 102 and other components of IHS 100. An input device 106 is coupled to processor 102 to provide input to processor 102. Examples of input devices may include keyboards, touchscreens, pointing devices such as mouses, trackballs, and trackpads, and/or a variety of other input devices known in the art. Programs and data are stored on a mass storage device 108, which is coupled to processor 102. Examples of mass storage devices may include hard discs, optical disks, magneto-optical discs, solid-state storage devices, and/or a variety other mass storage devices known in the art. IHS 100 further includes a display 110, which is coupled to processor 102 by a video controller 112. A system memory 114 is coupled to processor 102 to provide the processor with fast storage to facilitate execution of computer programs by processor 102. Examples of system memory may include random access memory (RAM) devices such as dynamic RAM (DRAM), synchronous DRAM (SDRAM), solid state memory devices, and/or a variety of other memory devices known in the art. In an embodiment, a chassis 116 houses some or all of the components of IHS 100. It should be understood that other buses and intermediate circuits can be deployed between the components described above and processor 102 to facilitate interconnection between the components and the processor 102.

Referring now to FIG. 2, an IHS chassis 200 is illustrated. In an embodiment, the IHS chassis 200 may be, for example, the chassis 116 described above with reference to FIG. 1 and may include some or all of the components of the IHS 100. In an embodiment, the IHS chassis 200 may be a portable IHS chassis, a notebook IHS chassis, and/or a variety of other IHS chassis known in the art. The IHS chassis 200 includes a base 202 having a bottom wall 202a and a plurality of side walls such as, for example, side walls 202b and 202c, that are orientated substantially perpendicularly to the bottom wall 202a and each other. An IHS housing 204 is defined between the bottom wall 202a and the side walls 202b and 202c. In the illustrated embodiment, various walls and components in the IHS chassis 200 have been removed for clarity of discussion, and one of skill in the art will recognize that various other structural members and components may be included in the IHS chassis 200. A fluid intake 206 is defined by the bottom wall 202a and includes a plurality of aperture that extend through the bottom wall 202a to provide an fluid passageway from outside the IHS chassis 200 to the IHS housing 204. A plurality of fan chassis securing members 208a and 208b are located on opposing sides of the fluid intake 206. A heat sink 210 is coupled to a heat producing component (located between the heat sink 210 and the bottom wall 202a of the IHS chassis 200 in the illustrated embodiment) that is mounted to the bottom wall 202a adjacent the fluid intake 206 and that may include, for example, the processor 102 described above with reference to FIG. 1 and/or a variety of other heat producing components known in the art.

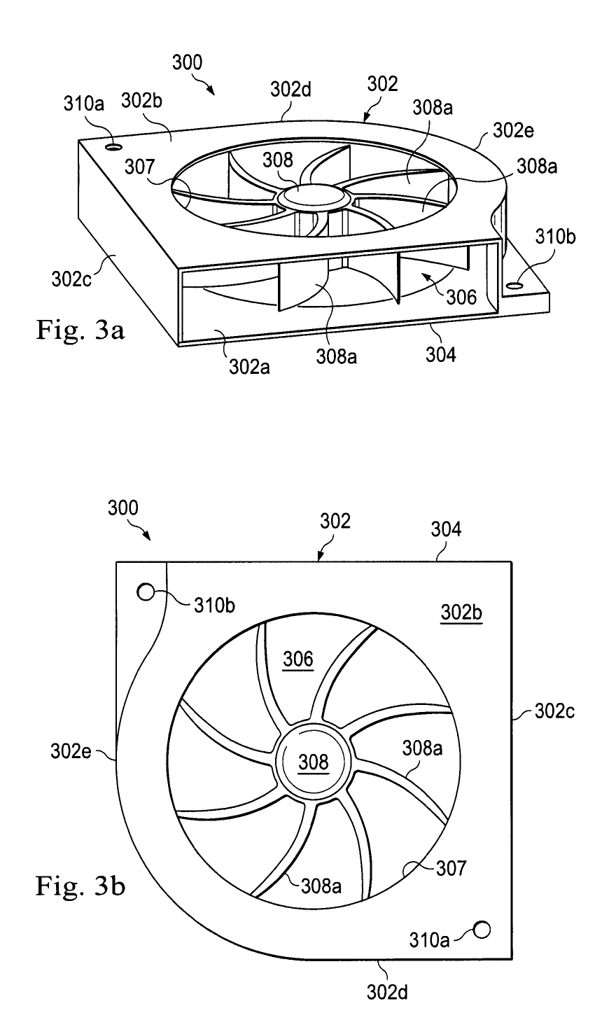

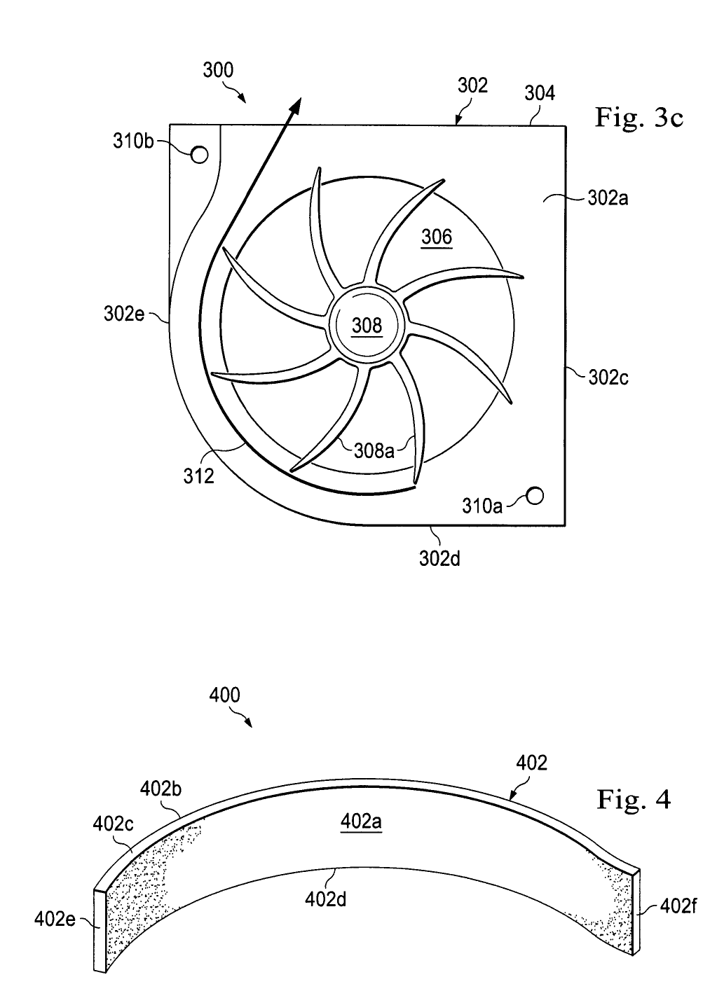

Referring now to FIGS. 3a, 3b and 3c, a fan chassis 300 is illustrated. The fan chassis 300 includes a base 302 having a bottom wall 302a, a top wall 302b located opposite the bottom wall 302a, a side wall 302c extending between the bottom wall 302a and the top wall 302b, a rear wall 302d extending between the bottom wall 302a and the top wall 302b and oriented substantially perpendicularly to the side wall 302c, and a filter coupling wall 302e extending between the bottom wall 302a and the top wall 302b, extending from the side wall 302d, and located opposite the side wall 302c. A fluid outlet 304 is defined along an edge of each of the bottom wall 302a, the top wall 302b, the side wall 302c, and the filter coupling wall 302e. The fluid outlet 304 provides access to a fan housing 306 that is defined between the bottom wall 302a, the top wall 302b, the side wall 302c, the rear wall 302d, and the filter coupling wall 302e. A fluid inlet 307 is defined by the top wall 302b, and a similar fluid inlet may be defined by the bottom wall 302a, in order to allow fluid to enter the fan housing 306. A fan 308 including a plurality of fan members 308a is located in the fan housing 306. In the illustrated embodiment, the fan 308 is a centrifugal fan. A plurality of chassis securing members 310a and 310b are located on opposing sides of the fan chassis 300. FIG. 3c is an illustration of the fan chassis 300 with the top wall 302b removed such that a fluid flow path 312 that is defined in the fan housing 306 may be seen. The fluid flow path is defined from the fan 308, through the fluid outlet 304, and out of the fan chassis 300. In an embodiment, the fluid flow path is the path of a fluid flow that is created by the fan members 308a during operation of the fan 308 and includes the intended direction of a majority of the fluid directed by the fan 308 during operation. In the illustrated embodiment, the fluid flow path 312 is located adjacent the filter coupling wall 302.

Referring now to FIG. 4, a debris filter 400 is illustrated. The debris filter 400 includes a base 402 having a front surface 402a, a rear surface 402b located opposite the front surface 402a, a top edge 402c extending between the front surface 402a and the rear surface 402b, a bottom edge 402d located opposite the top edge 402b and extending between the front surface 402a and the rear surface 402b, and a pair of opposing side edges 402e and 402f extending between the front surface 402a, the rear surface 402b, the top edge 402c, and the bottom edge 402d. In an embodiment, the debris filter 400 may include an adhesive material on the front surface 402a that is operable to accumulate debris. In an embodiment, the debris filter 400 may include an adhesive material on the rear surface 402b that is operable to couple the debris filter 400 to a surface.

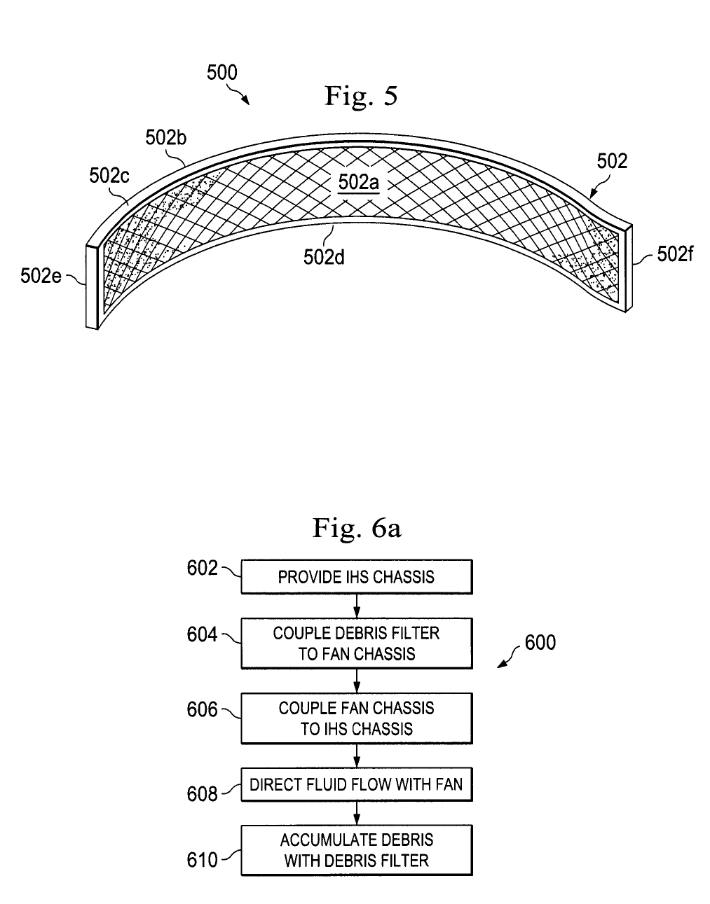

Referring now to FIG. 5, a debris filter 500 is illustrated. The debris filter 500 includes a base 502 having a front surface 502a, a rear surface 502b located opposite the front surface 502a, a top edge 502c extending between the front surface 502a and the rear surface 502b, a bottom edge 502d located opposite the top edge 502b and extending between the front surface 502a and the rear surface 502b, and a pair of opposing side edges 502e and 502f extending between the front surface 502a, the rear surface 502b, the top edge 502c, and the bottom edge 502d. In an embodiment, the debris filter 500 may include material that is operable to accumulate debris. In an embodiment, the debris filter 500 may include an adhesive material on the rear surface 502b that is operable to couple the debris filter 500 to a surface.

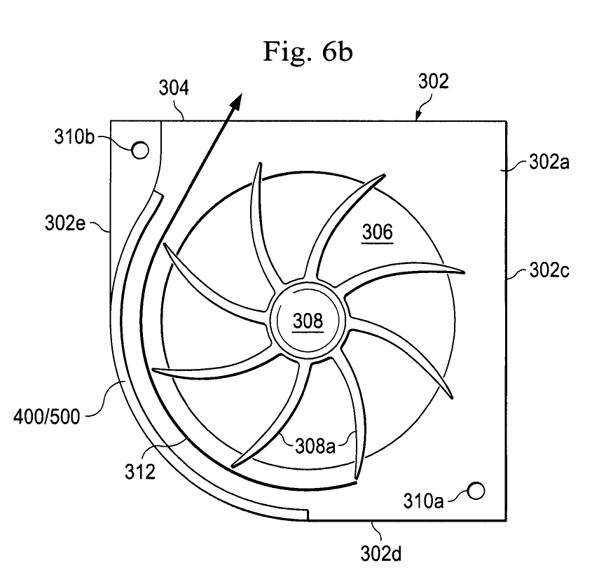

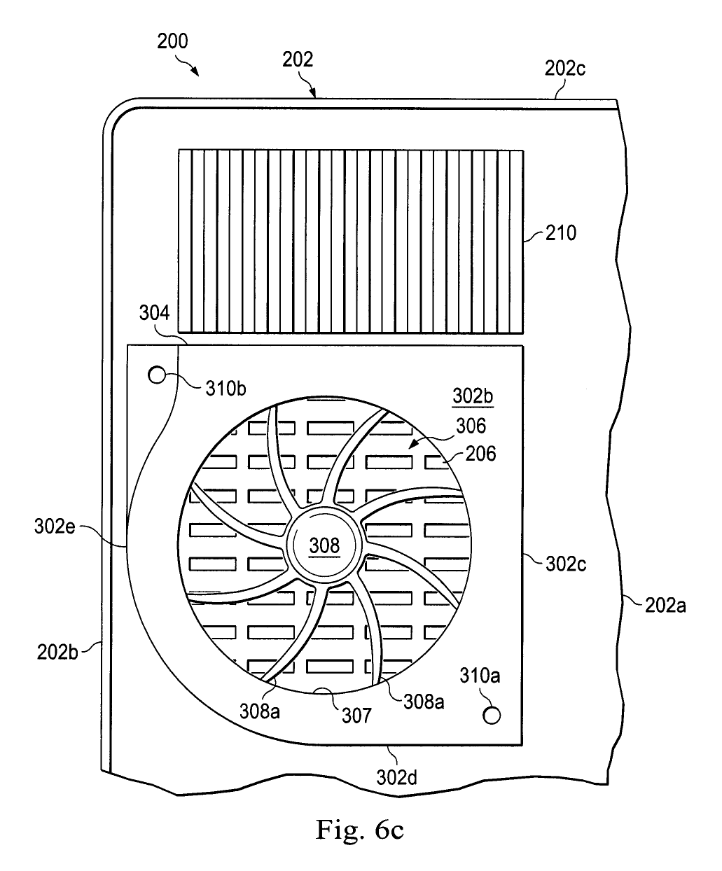

Referring now to FIGS. 3, 4, 5, 6a and 6b, a method 600 for filtering debris from a cooling system is illustrated. The method 600 begins at block 602 where an IHS chassis is provided. In an embodiment, the IHS chassis 200, described above with reference to FIG. 2, is provided. The method 600 then proceeds to block 604 where a debris filter is coupled to a fan chassis. In an embodiment, the debris filter 400 may include an adhesive on the rear surface 402b such that the rear surface 402b of debris filter 400 may be coupled to filter coupling wall 302e. With the rear surface 402b of the debris filter 400 coupled to the filter coupling wall 302e, the debris filter 400 is located in the fan housing 306 adjacent the fluid flow path outer boundary 312, with the front surface 402a of the debris filter 400 facing the fan 308, as illustrated in FIG. 6b. In another embodiment, the debris filter 500 may include an adhesive on the rear surface 502b such that the rear surface 502b of debris filter 500 may be coupled to filter coupling wall 302e. With the rear surface 502b of the debris filter 500 coupled to the filter coupling wall 302e, the debris filter 500 is located in the fan housing 306 adjacent the fluid flow path 312, with the front surface 502a of the debris filter 500 facing the fan 308, as illustrated in FIG. 6b. In an embodiment, the surface of the filter coupling wall 302e that is located in the fan housing 306 may be accessed in block 604 of the method 600, for example, by removing one of walls on the fan chassis 300, through the fluid outlet 304, and/or in a variety of other manners that would be apparent to one of skill in the art. Furthermore, while the debris filters 400 and 500 have been described as being coupled to the filter coupling wall 302e, in an embodiment, the debris filters 400 or 500 may be integral to the filter coupling wall 302e.

Referring now to FIGS. 6a and 6c, the method 600 then proceeds to block 606 where the fan chassis is coupled to the IHS chassis. The fan chassis 300 including either of the debris filters 400 or 500 may be coupled to the IHS chassis 200 by positioning the fan chassis 300 adjacent the bottom wall 202a of the IHS chassis 200 such that the chassis securing members 310a and 310b on the fan chassis 300 align with the fan chassis securing members 208a and 208b, respectively, on the IHS chassis 200. A fastener (not illustrated) may be used to engage of the chassis securing member 310a and the fan chassis securing member 208a, and a fastener (not illustrated) may be used to engage of the chassis securing member 310b and the fan chassis securing member 208b in order to secure the fan chassis 300 to the IHS chassis 200. With the fan chassis 300 secured to the IHS chassis 200, the fan 308 housed in the fan chassis 300 is located adjacent the fluid intake 206 defined by the IHS chassis 200, and the fluid outlet 304 defined by the fan chassis 300 is located adjacent the heat sink 210, as illustrated in FIG. 6c. In an embodiment, blocks 604 and 606 of the method 600 may be reversed (i.e., the fan chassis 300 may be coupled to the IHS chassis 200 before the debris filters 400 or 500 are coupled to the fan chassis 300).

Referring now to FIGS. 4, 5, 6a, 6b and 6c, the method 600 then proceeds to blocks 608 and 610 where a fluid flow is directed by the fan and debris is accumulated with the debris filter. Upon operation of the fan 308, fluid (e.g., air) is drawn, for example, through the fluid intake 206 defined by the IHS chassis 200, through the fluid inlet defined by the bottom wall 302a of the fan chassis 300, and into the fan housing 306. The fluid is directed by the fan members 308a out from the fan 308 and towards the walls 302c, 302d and 302e of the fan chassis 300 to create a fluid flow that, in an embodiment, follows the fluid flow path 312. The fluid flow follows the fluid flow path 312 from the fan, through the fan housing 306, out of the fluid outlet 304, and through the heat sink 210. The fluid in the fluid flow tends to include debris, and that debris typically includes both relatively large debris particles and relatively small debris particles that are small relative to relatively large debris particles. In traditional cooling systems, it has been determined that while some of the relatively small debris particles may accumulate at a fluid intake of the heat sink 210, the majority of the relatively small debris particles either pass through the heat sink 210 or do not effect the heat sink 210. However, the relatively large debris particles (e.g., human hair, animal hair, large dust particles, etc.) are much more likely to accumulate at the fluid intake of the heat sink 210. As more and more of the relatively large debris particles accumulate at the fluid intake of the heat sink 210, more and more of the relatively small debris particles are able to accumulate at the fluid intake of the heat sink 210 with the help of the accumulated large debris particles, eventually creating a situation that impedes the fluid flow to the heat sink 210 and can cause overheating of the IHS component coupled to the heat sink 210. However, it has also been determined that the relatively small debris particles, each having a relatively small mass relative to the relatively large debris particles, tend to remain in the fluid flow path 312 created by the fan 308, while the relatively large debris particles, each having a relatively large mass relative to the relatively small debris particles, tend to leave the fluid flow path 312 and make contact with a surface on the fan chassis 300. By positioning the debris filter 400 or 500 on the filter coupling wall 302e such that it is located adjacent the fan 308, the relatively large debris particles can be captured by the debris filter 400 or 500 when they leave the fluid flow path 312 such that the relatively large debris particles are accumulated on the debris filter 400 or 500 rather than at the fluid intake of the heat sink 210, which in turn lessens the ability of the relatively small debris particles to accumulate (as discussed above) and prevents the debris in the fluid flow from impeding the fluid flow to the heat sink 210. Furthermore, by positioning the debris filter 400 or 500 on the filter coupling wall 302e adjacent the fluid flow path, the debris filter 400 or 500 is located in the fan chassis 300 such that the debris filter 400 or 500 does not significantly obstruct the fluid flow from the fan 308, through the fluid outlet 304, and to the heat sink 210 relative to conventional debris filters. While the debris filter 400 or 500 coupled to the filter coupling wall 302e may slightly effect the fluid flow from the fan 308 as it flows past the debris filter 400 or 500, one of skill in the art will recognize that the majority of the fluid flow created by the fan 308 is allowed to flow freely from the fan 308 and through the fluid outlet 304 free of obstructions, as opposed to conventional debris filters which are positioned between the fan 308 and the fluid outlet 304 (or the fluid intake of the heat sink 210) such that the majority of the fluid flow created by the fan 308 must pass through the debris filter. Thus, a cooling system with a debris filter is provided that filters debris from the cooling system such that the debris does not accumulate and impede fluid flow, while increasing the cooling efficiency of the system by not creating an obstruction to the fluid flow that would require the fan to work harder to create the fluid flow relative to a system with no debris filter. In an embodiment, the debris filters 400 or 500 may be removed from the filter coupling wall 302e (e.g., by ‘peeling’ the debris filter 400 or 500 from the filter coupling wall 302e using a tab (not illustrated) located on the debris filter 400 or 500) and either cleaned or replaced with a new debris filter when the existing debris filter has become saturated with debris.

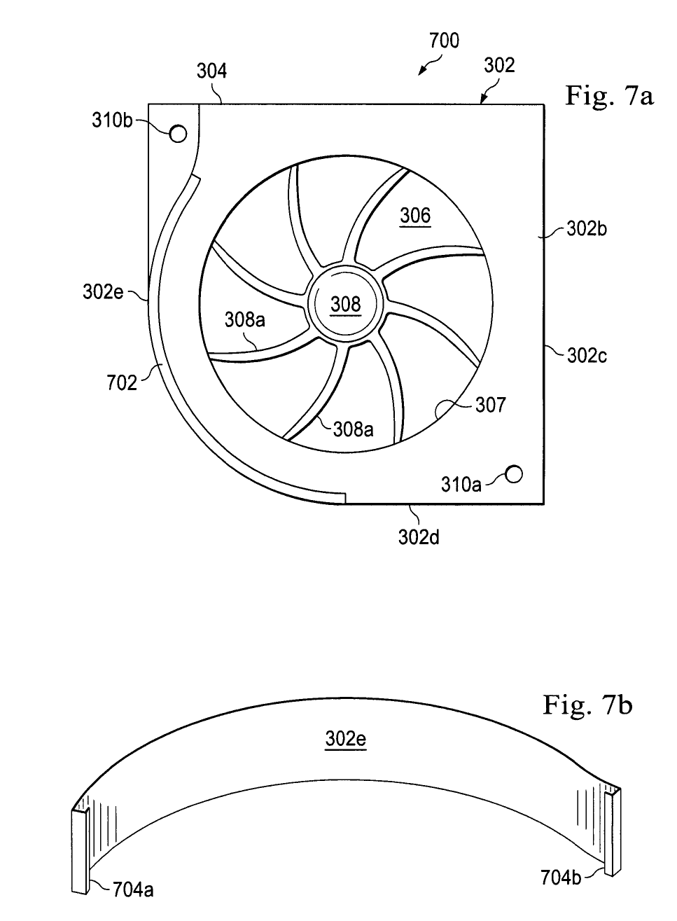

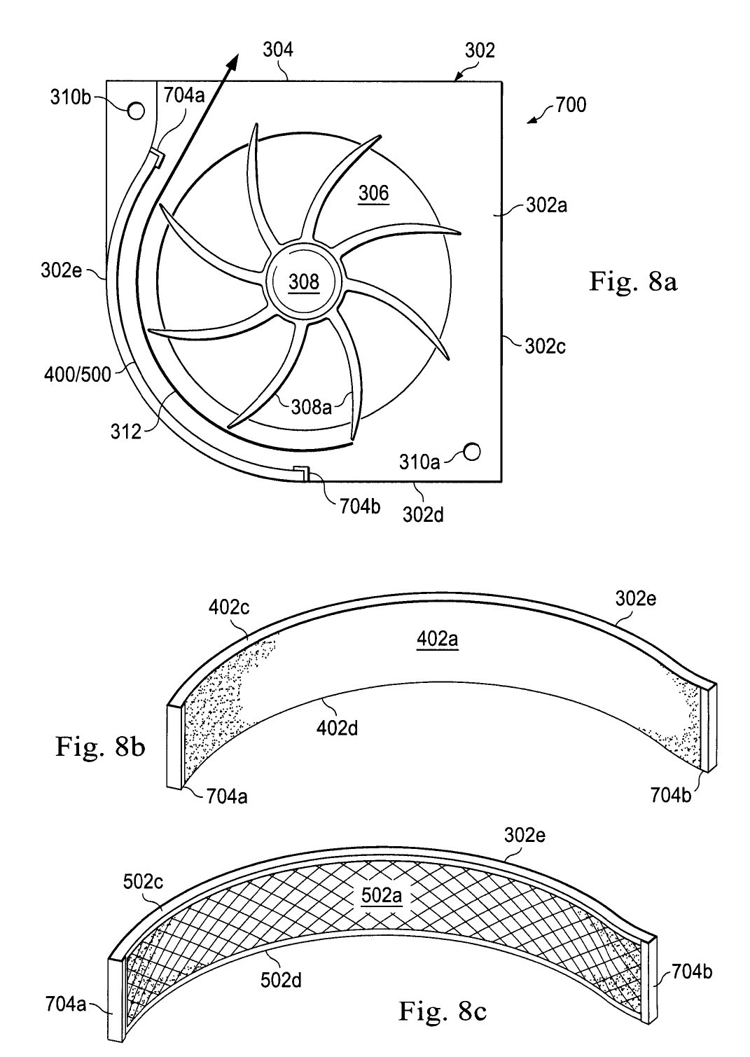

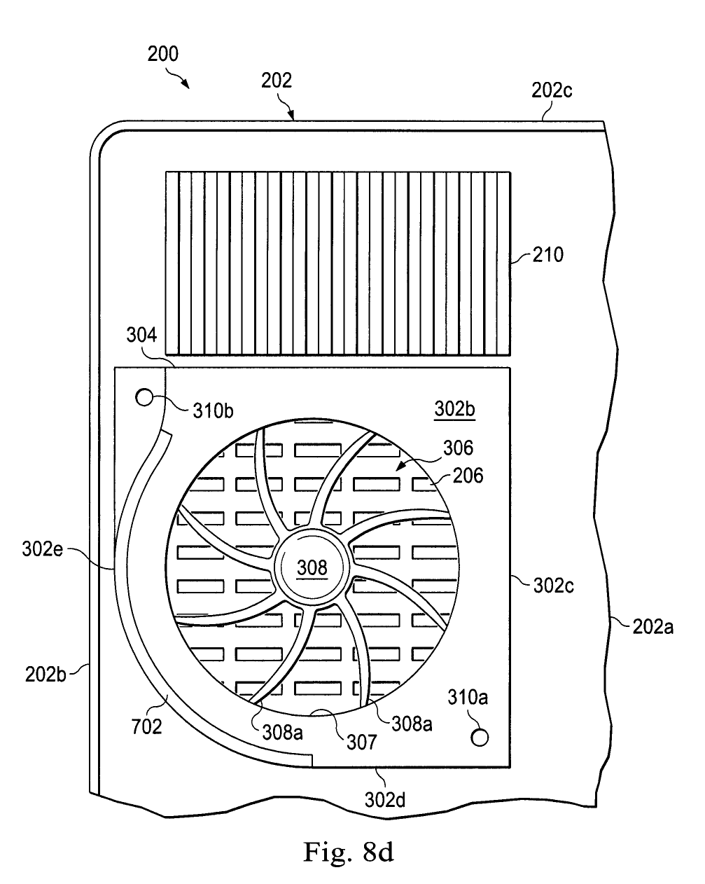

Referring now to FIGS. 7a, 7b, 8a, 8b, 8c and 8d, a fan chassis 700 is illustrated that is substantially similar in structure and operation to the fan chassis 300, described above with reference to FIGS. 3a, 3b and 3c, with the provision of a modified top wall 302b and filter coupling wall 302e. The top wall 302b of the fan chassis 700 defines a filter coupling passageway 702 that is located adjacent the filter coupling wall 302e and that extends through the top wall 302b to the fan housing 306, as illustrated in FIG. 7a. The filter coupling wall 302e includes a pair of debris filter coupling members 704a and 704b that are oriented on the debris filter coupling wall 302e in a spaced apart relationship from each other and extend from the filter coupling wall 302e, as illustrated in FIG. 7b. In operation, the fan chassis 700 may be used in a similar manner to the fan chassis 300 according to the method 600, with the provision of a modified block 604. In an embodiment, at block 604, the debris filter 400 may be coupled to the fan chassis 700 by positioning the debris filter 400 adjacent the fan chassis 700 such that the bottom edge 402d of the debris filter 400 is adjacent the filter coupling passageway 702. The debris filter 400 may then be moved through the filter coupling passageway 702 such that the side edges 402e and 402f of the debris filter 400 engage the debris filter coupling members 704a and 704b and coupled the debris filter 400 to the filter coupling wall 302e, as illustrated in FIG. 8b. In an embodiment, at block 604, the debris filter 500 may be coupled to the fan chassis 700 by positioning the debris filter 500 adjacent the fan chassis 700 such that the bottom edge 502d of the debris filter 500 is adjacent the filter coupling passageway 702. The debris filter 500 may then be moved through the filter coupling passageway 702 such that the side edges 502e and 502f of the debris filter 400 engage the debris filter coupling members 704a and 704b and coupled the debris filter 500 to the filter coupling wall 302e, as illustrated in FIG. 8c. The fan chassis 700 may then be coupled to the IHS chassis 200, as illustrated in FIG. 8d, and operated according to the method 600 in substantially the same manner as described above.

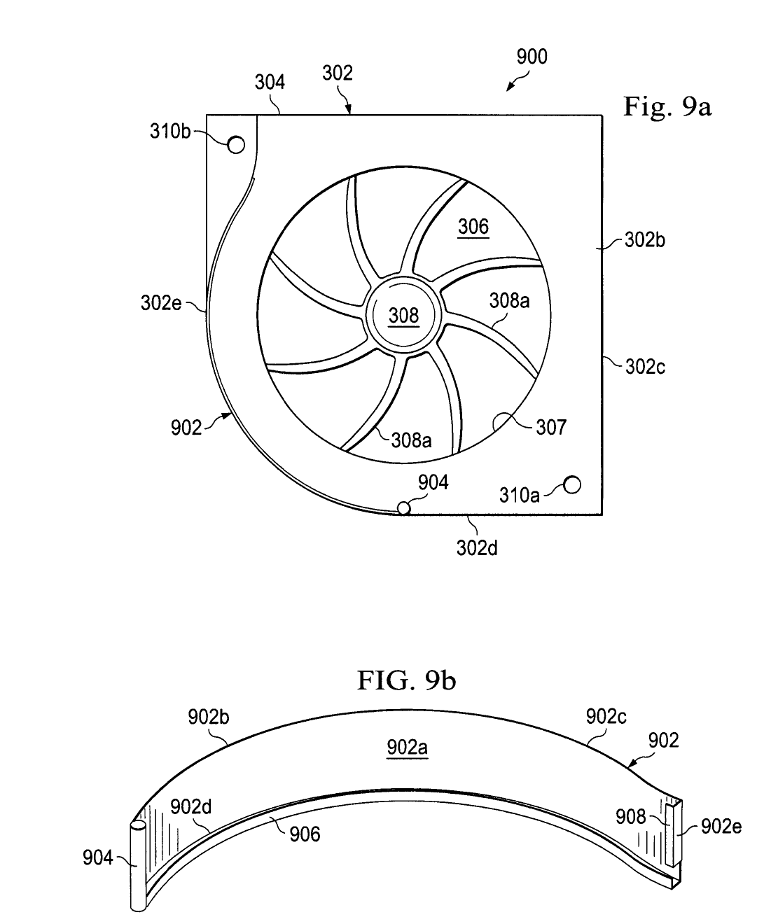

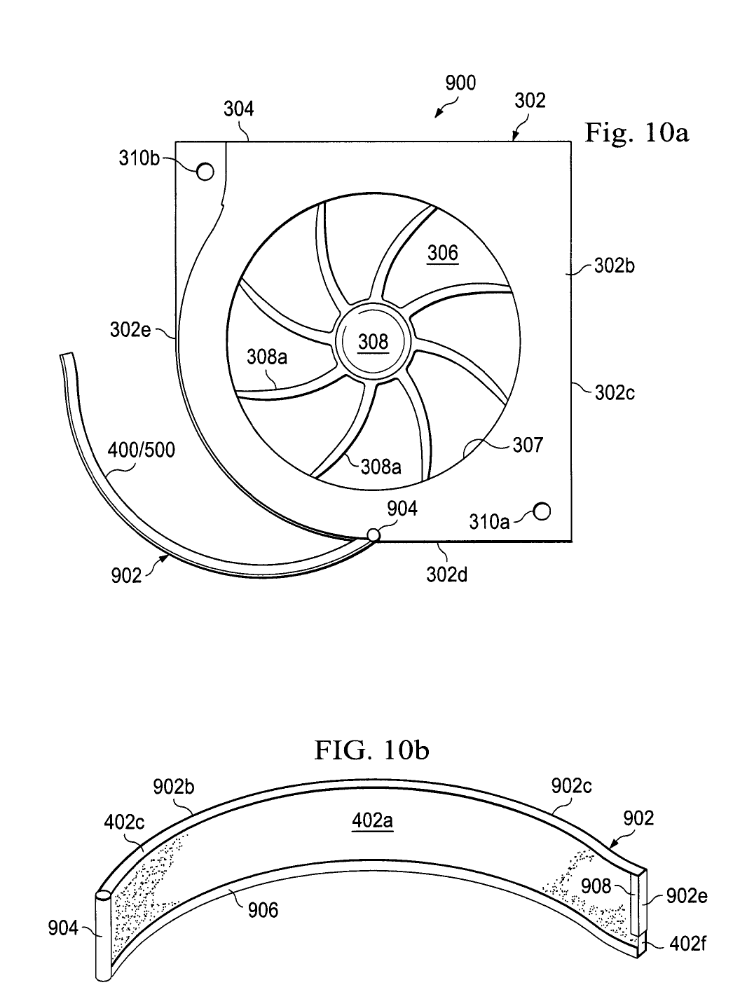

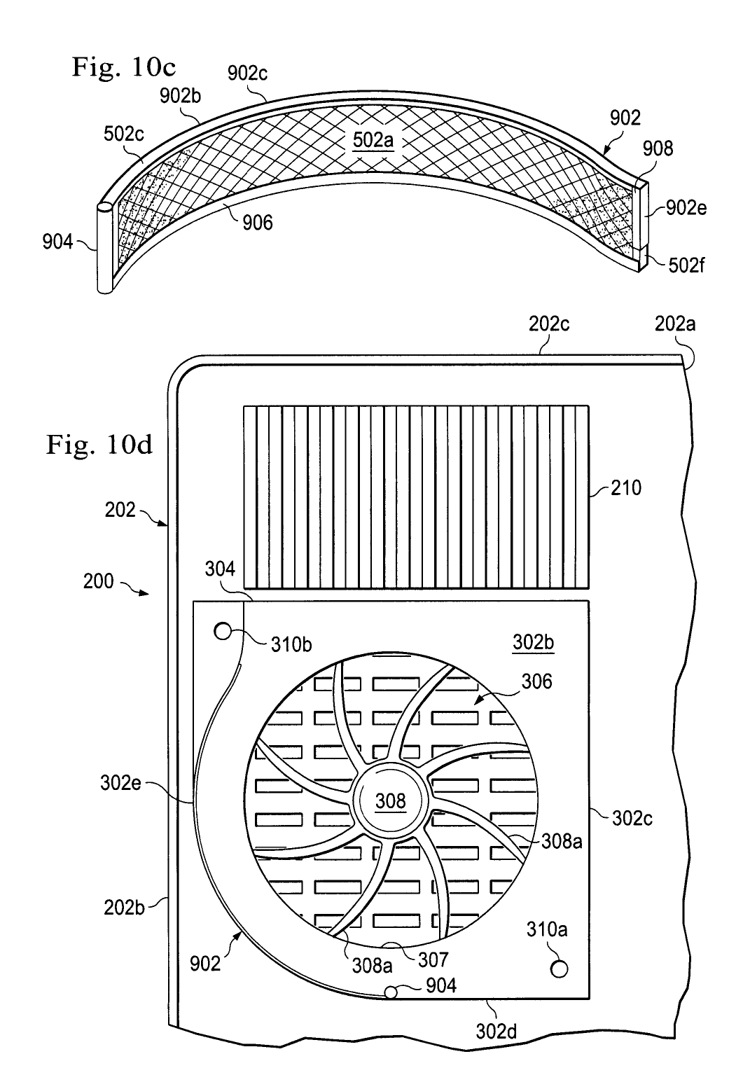

Referring now to FIGS. 9a, 9b, 10a, 10b, 10c, 10d and 10e, a fan chassis 900 is illustrated that is substantially similar in structure and operation to the fan chassis 300, described above with reference to FIGS. 3a, 3b and 3c, with the provision of a modified filter coupling wall 302e. At least a portion of the filter coupling wall 302e includes a door 902 that is coupled to the fan chassis 300 by a hinge 904, as illustrated in FIG. 9a. The door 902 includes a front surface 902a, a rear surface 902b located opposite the front surface 902a, a top edge 902c extending between the front surface 902a and the rear surface 902b, a bottom edge 902d located opposite the top edge 902b and extending between the front surface 502a and the rear surface 502b, and a side edge 902e extending between the front surface 502a, the rear surface 502b, the top edge 502c, and the bottom edge 502d. The hinge 904 is located on the door 902 opposite the side edge 902e. A debris coupling member 906 extends along the bottom edge 902d of the door 902 and a debris coupling member 908 extends from the side edge 902e of the door 902, as illustrated in FIG. 9b. The door 902 is operable to move relative to the fan chassis 900 about the hinge 904, as illustrated in FIG. 10a. While the door 902 has been described and illustrated as pivotally coupled to the fan chassis 900 by the hinge 904, one of skill in the art will recognize that the door 902 may be moveably coupled to the fan chassis 900 in a variety of manners. Furthermore, one of skill in the art will recognize that the door 902 and debris filter 400 or 500 may be integrated, and the door 902 may be removable from the fan chassis 900 rather than pivotable relative to the fan chassis 900. In operation, the fan chassis 900 may be used in a similar manner to the fan chassis 300 according to the method 600, with the provision of a modified block 604. In an embodiment, at block 604, the debris filter 400 may be coupled to the fan chassis 900 by moving the door 902 relative to the fan chassis 900 (or removing the door 902 from the fan chassis 900) and positioning the debris filter 400 such that the bottom edge 402d and the side edge 402f of the debris filter 400 engage the debris filter coupling members 906 and 908, respectively, to couple the debris filter 400 to the door 902 of the filter coupling wall 302e, as illustrated in FIG. 10b. In an embodiment, at block 604, the debris filter 500 may be coupled to the fan chassis 900 by moving the door 902 relative to the fan chassis 900 (or removing the door 902 from the fan chassis 900) and positioning the debris filter 500 such that the bottom edge 502d and the side edge 502f of the debris filter 500 engage the debris filter coupling members 906 and 908, respectively, to couple the debris filter 500 to the door 902 of the filter coupling wall 302e, as illustrated in FIG. 10c. The fan chassis 700 may then be coupled to the IHS chassis 200, as illustrated in FIG. 10d, and operated according to the method 600 in substantially the same manner as described above.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A cooling system, comprising:
a fan chassis housing a fan;
a fluid outlet defined by the fan chassis and located adjacent the fan such that a fluid flow path is defined from the fan, through the fluid outlet, and out of the fan chassis;
a filter coupling wall located in the fan chassis and adjacent to the fluid flow path; and
a debris filter located along the filter coupling wall and adjacent to at least a portion of the fluid flow path.

2. The system of claim 1, wherein the filter coupling wall is moveably coupled to the chassis.

3. The system of claim 1, wherein filter coupling wall comprises a debris filter coupling member.

4. The system of claim 1, wherein the debris filter is coupled to the filter coupling wall by an adhesive.

5. The system of claim 1, wherein the fan is oriented in the fan chassis in order to direct a fluid flow along the fluid flow path, and wherein the debris filter located along the filter coupling wall is operable to accumulate debris that leaves the fluid flow path.

6. The system of claim 1, wherein the debris filter is located in the fan chassis such that the debris filter does not obstruct a fluid flow through the fluid outlet.

7. The system of claim 1, wherein the fan comprises a centrifugal fan.

8. An information handling system (IHS), comprising:
an IHS chassis;
a heat producing component located in the IHS chassis;
a fan chassis located adjacent the heat producing component;
a fan housed in the fan chassis;
a fluid outlet defined by the fan chassis and located between the heat producing component and the fan such that a fluid flow path is defined from the fan, through the fluid outlet, and to the heat producing component;
a filter coupling wall located in the fan chassis and adjacent to the fluid flow path; and
a debris filter located along the filter coupling wall and adjacent to at least a portion of the fluid flow path.

9. The system of claim 8, further comprising:
a heat sink coupled to the heat producing component, wherein the fluid flow path defined to the heat producing component is further defined through the heat sink.

10. The system of claim 8, wherein the filter coupling wall is moveably coupled to the chassis.

11. The system of claim 8, wherein filter coupling wall comprises a debris filter coupling member.

12. The system of claim 8, wherein the debris filter is coupled to the filter coupling wall by an adhesive.

13. The system of claim 8, wherein the fan is oriented in the fan chassis in order to direct a fluid flow along the fluid flow path, and wherein the debris filter located along the filter coupling wall is operable to accumulate debris that leaves the fluid flow path.

14. The system of claim 8, wherein the debris filter is located in the fan chassis such that the debris filter does not obstruct a fluid flow through the fluid outlet.

15. The system of claim 8, wherein the fan comprises a centrifugal fan.

16. The system of claim 8, further comprising:
a fluid intake defined by the IHS chassis and located adjacent the fan chassis in order to provide a fluid source for the fan.

17. A method for filtering debris from a cooling system, comprising:
providing a heat producing component and a fan chassis located adjacent the heat producing component, wherein the fan chassis defines a fluid outlet and houses a fan that is located adjacent the fluid outlet, and wherein a fluid flow path is defined from the fan, through the fluid outlet, and to the heat producing component;
directing a fluid flow from the fan along the fluid flow path; and
accumulating debris that leaves the fluid flow path in a debris filter that is located in the fan chassis and adjacent at least a portion of the fluid flow path.

18. The method of claim 17, further comprising;
moving a filter coupling wall that is located on the fan chassis to provide access to the debris filter.

19. The method of claim 17, wherein the fan comprises a centrifugal fan.

20. The method of claim 17, wherein the debris filter is located in the fan chassis such that the debris filter does not obstruct a fluid flow through the fluid outlet.
